(19) United States
(12) Patent Application Publication
(10) Pub. No.: US 2026/0129852 A1
(43) Pub. Date: May 7, 2026

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 19/175,426

(22) Filed: Apr. 10, 2025

(30) Foreign Application Priority Data
Nov. 4, 2024 (KR) 10-2024-0154631

(51) Int. Cl. H10B 43/27; H10B 41/10; H10B 41/27; H10B 41/40; H10B 43/10; H10B 43/40

(52) U.S. Cl. CPC H10B 43/27; H10B 41/10; H10B 41/27; H10B 41/40; H10B 43/10; H10B 43/40

(57) ABSTRACT

A semiconductor device includes a substrate including a first region and a second region, a gate structure positioned over the substrate and extending from the first region to the second region, a stack positioned in the second region over the substrate, first supports extending through the gate structure in the first region and successively arranged in a first direction, and a second support extending in a second direction intersecting the first direction between the gate structure and the stack in the second region, at least one of the first supports may include a first protrusion protruding toward the second region, and the second support may include a second protrusion protruding toward the first region.

### CROSS-REFERENCE TO RELATED APPLICATION

The present application claims priority under 35 U.S.C. § 119(a) to Korean Patent Application No. 10-2024-0154631 filed on Nov. 4, 2024, in the Korean Intellectual Property Office, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a substrate including a first region and a second region, a gate structure positioned over the substrate and extending from the first region to the second region, a stack positioned in the second region over the substrate, first supports extending through the gate structure in the first region and successively arranged in a first direction, and a second support extending in a second direction intersecting the first direction between the gate structure and the stack in the second region, at least one of the first supports may include a first protrusion protruding toward the second region, and the second support may include a second protrusion protruding toward the first region.

According to an embodiment of the present disclosure, a semiconductor device may include a gate structure including a first portion and a second portion positioned on the first portion, a stack positioned at a level corresponding to the gate structure, first supports extending through the gate structure and successively arranged in a first direction, and a second support extending in a second direction intersecting the first direction between the gate structure and the stack, at least one of the first supports may include a first protrusion protruding toward the second support, the second support may include a second protrusion protruding toward the first supports, and at least one of the first protrusion or the second protrusion may be positioned at a level corresponding to the first portion.

According to an embodiment of the present disclosure, a method of manufacturing a semiconductor device may include forming a first sub-stack, forming a first support hole extending through the first sub-stack, forming a support sacrificial layer in the first support hole, forming a second sub-stack on the first sub-stack, forming a second support hole extending through the second sub-stack and the first sub-stack and exposing a sidewall of the support sacrificial layer, removing the support sacrificial layer through the second support hole, and forming a support in the first support hole and the second support hole.

According to an embodiment of the present disclosure, a method of manufacturing a semiconductor device may include forming a first sub-stack, forming a first channel hole extending through the first sub-stack, forming a first support hole extending through the first sub-stack, forming a channel sacrificial layer in the first channel hole, forming a support sacrificial layer in the first support hole, forming a second sub-stack on the first sub-stack, forming a second support hole extending through the second sub-stack and the first sub-stack and exposing a sidewall of the support sacrificial layer, removing the support sacrificial layer through the second support hole, and forming a support including a protrusion in the first support hole and the second support hole.

### BRIEF DESCRIPTION OF THE DRAWINGS

FIGS. 1A, 1B, 1C, and 1D are drawings illustrating a semiconductor device according to an embodiment of the present disclosure.

FIGS. 2A, 2B, 2C and 2D are drawings illustrating a semiconductor device according to an embodiment of the present disclosure.

FIGS. 3A, 3B, 3C, 3D, and 3E are drawings illustrating a method of manufacturing a semiconductor device according to an embodiment of the present disclosure.

FIGS. 4A, 4B, 4C, and 4D, 5A, 5B, 5C, and 5D, 6A, 6B, 6C, and 6D, 7A, 7B, 7C, and 7D, and 8A, 8B, 8C, and 8D are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to an embodiment of the present technology, a semiconductor device having a stable structure and improved reliability may be provided.

Hereinafter, embodiments according to the technical spirit of the present disclosure are described with reference to the accompanying drawings.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

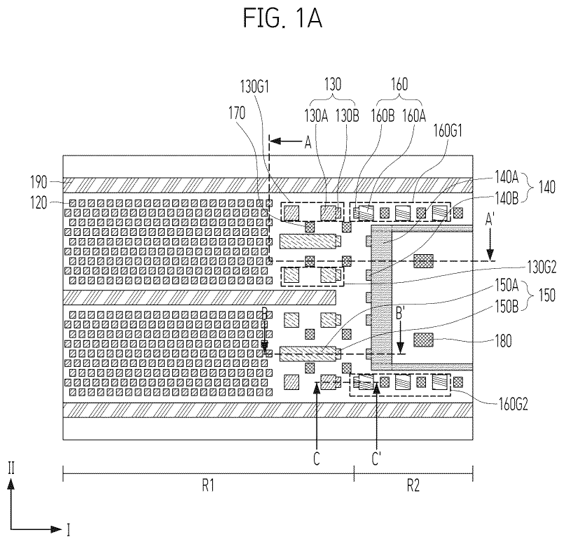

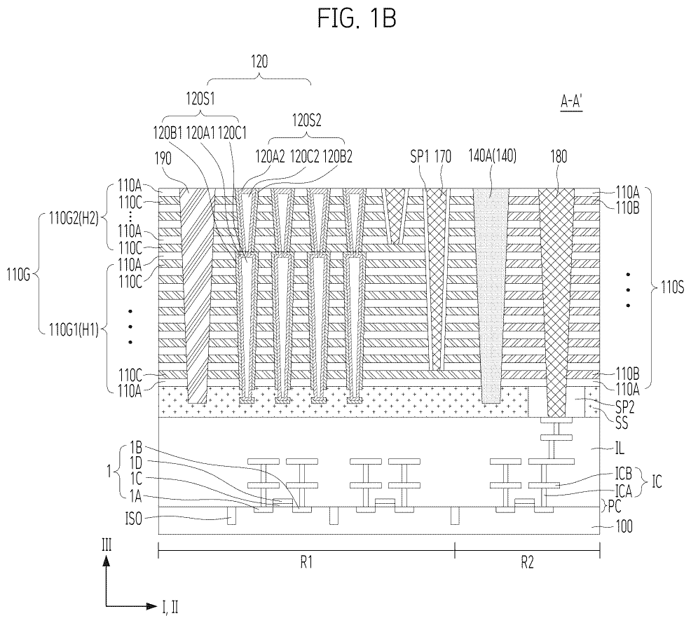

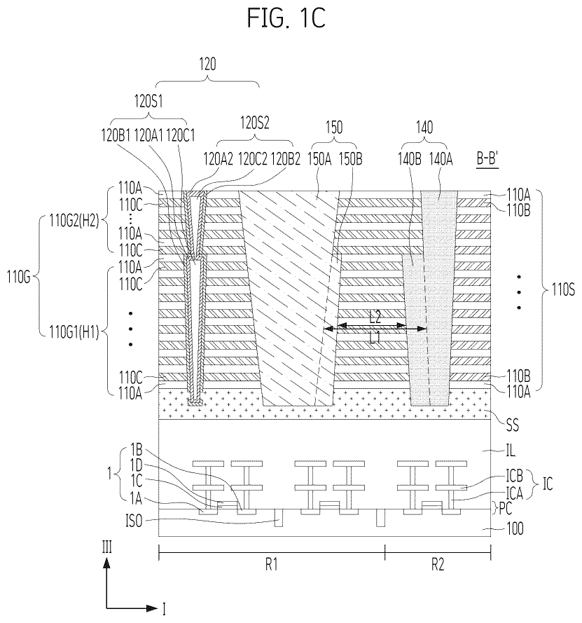

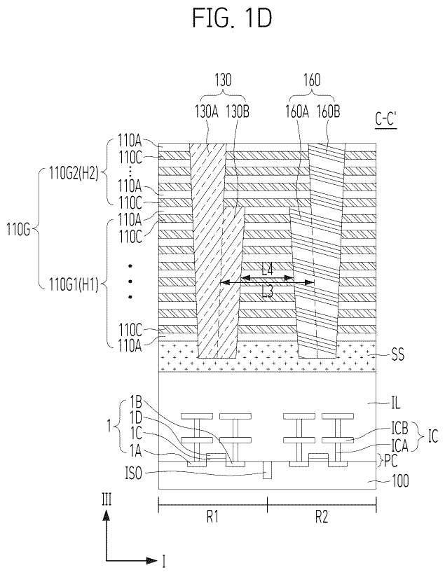

FIGS. 1A to 1D are drawings illustrating a semiconductor device according to an embodiment of the present disclosure. FIG. 1A is a plan view, FIG. 1B is a cross-sectional view taken along line A-A′ of FIG. 1A, FIG. 1C is a cross-sectional view taken along line B-B′ of FIG. 1A, and FIG. 1D is a cross-sectional view taken along line C-C′ of FIG. 1A.

Referring to FIGS. 1A to 1D, the semiconductor device may include a substrate 100, a peripheral circuit PC, a stack 110S, a gate structure 110G, channel structures 120, first supports 130, and second supports 140. The semiconductor device may further include third supports 150, fourth supports 160, contact vias 170, contact plugs 180, slit structures 190, an interlayer insulating layer IL, an interconnection structure IC, an element isolation layer ISO, a source structure SS, a first insulating spacer SP1, and a second insulating spacer SP2.

The substrate 100 may include a first region R1 and a second region R2. The first region R1 and the second region R2 may be adjacent to each other in a first direction I. The first region R1 may be a region where memory cells are positioned. The second region R2 may be a region where the contact plugs 180 electrically connected to the peripheral circuit PC are positioned. The contact vias 170 respectively connected to conductive layers 110C of the gate structure 110G may be positioned in the first region R1 and the second region R2.

The peripheral circuit PC may be positioned on the substrate 100. For example, the peripheral circuit PC may be positioned in the second region R2. However, the present disclosure is not limited thereto, and the peripheral circuit PC may be positioned in the first region R1 and the second region R2. The peripheral circuit PC may include a transistor 1, a capacitor, and the like. The transistor 1 may include junctions 1A and 1B, a gate electrode 1D, and a gate insulating layer 1C. Here, the gate insulating layer 1C may be positioned between the gate electrode 1D and the substrate 100. The element isolation layer ISO may be positioned in the substrate 100, an active region may be defined by the element isolation layer ISO, and the transistor 1 may be positioned in the active region.

The interconnection structure IC may be positioned on the peripheral circuit PC. The interconnection structure IC may be positioned in the interlayer insulating layer IL. Here, the interlayer insulating layer IL may be positioned on the substrate 100. The interconnection structure IC may include vias ICA and lines ICB.

The interconnection structure IC may be connected to the peripheral circuit PC. For example, at least one of the vias ICA may be connected to the transistor 1. At least one of the vias ICA may interconnect the lines ICB. The lines ICB may interconnect the vias ICA. The interconnection structure IC may include a conductive material such as tungsten. The interlayer insulating layer IL may include an insulating material such as an oxide.

The source structure SS may be positioned on the interlayer insulating layer IL. The source structure SS may be a single layer or multiple layers. The source structure SS may include a conductive material such as polysilicon.

The gate structure 110G may be positioned over the substrate 100. The gate structure 110G may extend from the first region R1 to the second region R2. The gate structure 110G may include first insulating layers 110A and conductive layers 110C alternately stacked. The gate structure 110G may include a first portion 110G1 and a second portion 110G2 positioned on the first portion 110G1. For example, the gate structure 110G may include the first portion 110G1 having a first height H1 (i.e., 110G1(H1)) and the second portion 110G2 having a second height H2 (i.e., 110G2(H2)). Here, the first height H1 and the second height H2 may be substantially equal to each other or different from each other. For example, the second height H2 may be less than the first height H1.

The conductive layers 110C may be a gate line such as a source selection line, a word line, or a drain selection line. A source selection transistor, a memory cell, or a drain selection transistor may be positioned in a region where the channel structures 120 and the conductive layers 110C intersect. For example, at least one source selection transistor, a plurality of memory cells, and at least one drain selection transistor stacked along the channel structure 120 may configure one memory string. The conductive layers 110C may include a conductive material such as tungsten, molybdenum, or polysilicon.

The stack 110S may be positioned over the substrate 100. The stack 110S may be positioned in the second region R2. The stack 110S may include first insulating layers 110A and second insulating layers 110B alternately stacked. The second insulating layers 110B may be remains without being replaced with the conductive layers 110C in a process of manufacturing the semiconductor device. The first insulating layers 110A and the second insulating layers 110B may include different materials. For example, the first insulating layers 110A may include an insulating material such as an oxide, and the second insulating layers 110B may include a sacrificial material such as a nitride.

The channel structures 120 may be positioned in the first region R1, and may extend through the gate structure 110G. For example, the channel structures 120 may extend into the source structure SS through the gate structure 110G. Each of the channel structures 120 may include a first sub-channel structure 120S1 and a second sub-channel structure 120S2. For example, the channel structure 120 may include the first sub-channel structure 120S1 extending through the first portion 110G1, and may include the second sub-channel structure 120S2 extending through the second portion 120S2 and connected to the first sub-channel structure 120S1. The first sub-channel structure 120S1 may include a first sub-channel layer 120A1, a first sub-memory layer 120B1 surrounding the first sub-channel layer 120A1, and a first sub-insulating core 120C1 in the first sub-channel layer 120A1. The second sub-channel structure 120S2 may include a second sub-channel layer 120A2, a second sub-memory layer 120B2, and a second sub-insulating core 120C2 in the second sub-channel layer 120A2.

The first supports 130 may be positioned in the first region R1 and may extend through the gate structure 110G. The first supports 130 may be successively arranged in the first direction I. For example, the first supports 130 successively arranged in the first direction I may configure a first group 130G1. In addition, the first supports 130 spaced apart from the first group 130G1 in a second direction II intersecting the first direction I and successively arranged in the first direction I may configure a second group 130G2.

The first supports 130 may include a first body portion 130A and/or a first protrusion 130B. For example, at least one of the first supports 130 may include the first body portion 130A and the first protrusion 130B. Here, the first body portion 130A may extend through the gate structure 110G, and the first protrusion 130B may protrude from the first body portion 130A within the gate structure 110G. For example, the first protrusion 130B may protrude from the first body portion 130A and remain in the gate structure 110G. For example, the first protrusion 130B may protrude from the first body portion 130A and into the gate structure 110G. The first protrusion 130B may protrude toward the second support 140. For example, the first protrusion 130B may protrude toward the second region R2. The first protrusion 130B may be positioned at a level corresponding to the first portion 110G1. For example, the first protrusion 130B may be positioned at a level corresponding to the first sub-channel structure 120S1. In an embodiment, the first protrusion 130B or the second protrusion 140B may be positioned at a level at least partially overlapping in the first direction I with the first portion 110G1 as shown in FIGS. 1C and 1D. In an embodiment, the stack 110S may be positioned at a level at least partially overlapping in the first direction I with the gate structure 110G as shown in FIG. 1B. In an embodiment, the first protrusion 130B or the second protrusion 140B may be positioned at a level at least partially overlapping in the first direction I with the first sub-channel structure 120S1 as shown in FIGS. 1B, 1C, and 1D. The second support 140 may include an insulating material such as an oxide.

The second support 140 may be positioned in the second region R2, and may extend between the gate structure 110G and the stack 110S. The second support 140 may extend in the second direction II. The second support 140 may include a second body portion 140A and a second protrusion 140B. Here, the number of the second protrusions 140B may be plural.

The second body portion 140A may extend between the gate structure 110G and the stack 110S. For example, the second body portion 140A may include first extensions extending in the first direction I and second extensions extending in the second direction II, and the first extensions may be interconnected by the second extension. In other words, the second body portion 140A may have a C shape. However, the disclosure is not limited thereto, and the second body portion 140A may also configure a closed region through the first extensions and a plurality of second extensions. The second protrusion 140B may protrude from the second body portion 140A within the gate structure 110G. For example, the second protrusion 140B may protrude from the second body portion 140A and remain in the gate structure 110G. For example, the second protrusion 140B may protrude from the second body portion 140A and into the gate structure 110G. The second protrusion 140B may protrude toward the first supports 130. For example, the second protrusion 140B may protrude toward the first region R1. The second protrusion 140B may be positioned at a level corresponding to the first portion 110G1. For example, the second protrusion 140B may be positioned at a level corresponding to the first sub-channel structure 120S1. The first supports 130 may include an insulating material such as an oxide.

The third supports 150 may be positioned in the first region R1 and may extend through the gate structure 110G. The third supports 150 may extend in the first direction I. For example, the third supports 150 may be positioned between the first group 130G1 of the first supports 130 and the second group 130G2 of the first supports 130, and may extend in the first direction I. At least one of the third supports 150 may include a third body portion 150A and/or a third protrusion 150B. Here, the third body portion 150A may extend through the gate structure 110G, and the third protrusion 150B may protrude toward the second region R2 within the gate structure 110G. For example, the third protrusion 150B may protrude from the third body portion 150A and remain in the gate structure 110G. For example, the third protrusion 150B may protrude from the third body portion 150A and into the gate structure 110G. The third protrusion 150B may be positioned at a level corresponding to the first sub-channel structure 120S1. The third supports 150 may include an insulating material such as an oxide.

The fourth supports 160 may be positioned in the second region R2 and may extend through the gate structure 110G. The fourth supports 160 may be successively arranged in the first direction I. For example, the fourth supports 160 successively arranged in the first direction I may configure a first group 160G1. In addition, the fourth supports 160 spaced apart from the first group 160G1 in the second direction II and successively arranged in the first direction I may configure the second group 160G2. Here, the second support 140 may be positioned between the first group 160G1 and the second group 160G2.

At least one of the fourth supports 160 may include a fourth body portion 160A and/or a fourth protrusion 160B. Here, the fourth body portion 160A may extend through the gate structure 110G, and the fourth protrusion 160B may protrude toward the first region R1 within the gate structure 110G. For example, the fourth protrusion 160B may protrude from the fourth body portion 160A and remain in the gate structure 110G. For example, the fourth protrusion 160B may protrude from the fourth body portion 160A and into the gate structure 110G. The fourth protrusion 160B may be positioned at a level corresponding to the first sub-channel structure 120S1. The fourth supports 160 may include an insulating material such as an oxide.

The contact vias 170 may extend through the gate structure 110G and may be respectively connected to the conductive layers 110C. Here, the first insulating spacers SP1 may surround a sidewall of the contact vias 170. The contact vias 170 may be positioned in the first region R1 and the second region R2. For example, the contact vias 170 may be positioned between the first supports 130 and the third supports 150, between the third supports 150, and/or between the first/third supports 130, and 150 and the second support 140. The first insulating spacers SP1 may include an insulating material such as an oxide, and the contact vias 170 may include a conductive material such as tungsten.

For reference, although not shown in this drawing, the gate structure 110G may include a step structure configured through the conductive layers 110C, and an interlayer insulating layer may be positioned on the step structure. Here, an upper surface of the conductive layers 110C and the interlayer insulating layer may be in contact with each other. Meanwhile, the contact vias 170 may extend through the interlayer insulating layer and may be respectively connected to the upper surface of the conductive layers 110C. In this case, the first insulating spacers SP1 may be omitted.

The contact plug 180 may be positioned in the second region R2 and may extend through the stack 110S. For example, the contact plug 180 may pass through the source structure SS through the stack 110S and may be electrically connected to the peripheral circuit PC. The contact plug 180 may be electrically connected to the peripheral circuit PC through the interconnection structure IC. Here, the second insulating spacers SP2 may surround a sidewall of the contact plug 180 in the source structure SS. The second insulating spacers SP2 may include an insulating material such as an oxide, and the contact plugs 180 may include a conductive material such as tungsten.

A region where the contact vias 170 are positioned and a region where the contact plugs 180 are positioned may be different from each other. For example, the contact vias 170 may be positioned in the first region R1 and the second region R2 and may extend through the gate structure 110G. On the other hand, the contact plugs 180 may be positioned in the second region R2 and may extend through the stack 110S.

The first, third, and fourth supports 130, 150, and 160 may be positioned between the contact vias 170, and the second support 140 may be positioned to surround the stack 110S to define a region where the stack 110S remains in the process of manufacturing the semiconductor device. In this case, shapes and arrangements of the first, second, third, and fourth supports 130, 140, 150, and 160 positioned in the first region R1 and the second region R2 may be different. For example, the first and third supports 130 and 150 may be arranged regularly in the first region R1, and the second and fourth supports 140 and 160 may be arranged regularly in the second region R2. In other words, regularity of the supports may be changed at a boundary between the first region R1 and the second region R2. Therefore, bending of the gate structure 110G and/or the stack 110S may occur at the boundary between the first region R1 and the second region R2, and this problem may become more severe as a height of the gate structure 110G and/or the stack 110S increases.

In addition, in an embodiment, in order to form the contact vias 170 at a portion where the regularity of the supports is changed, securing a margin between the first/third supports 130 and 150 and the second/fourth supports 140 and 160 is required. In an embodiment, when a distance between the first/third supports 130 and 150 and the second/fourth supports 140 and 160 is increased to secure the margin, the first, second, third, and fourth supports 130, 1400, 150, and 160 might not sufficiently support the gate structure 110G and/or the stack 110S. In other words, in an embodiment, support force of the first, second, third, and fourth supports 130, 140, 150, and 160 may be weakened near a boundary surface between the first region R1 and the second region R2.

According to an embodiment of the present disclosure, the first and third protrusions 130B and 150B protruding from the first region R1 toward the second region R2 may be included, and the second and fourth protrusions 140B and 160B protruding from the second region R2 toward the first region R1 may be included. In this case, in an embodiment, compared to a case where the first, second, third, and fourth protrusions 130B, 140B, 150B, and 160B do not exist, a thickness of the first, second, third, and fourth supports 130, 140, 150, and 160 may be increase, and a distance between the first/third supports 130 and 150 and the second/fourth supports 140 and 160 may become relatively shorter, and thus support force of the first, second, third, and fourth supports 130, 140, 150, and 160 may be improved.

For example, referring to FIG. 1C, a thickness of the second/third supports 140 and 150 may be increased compared to a case where only the second/third body portions 140A and 150A exist. In addition, a distance between the second support 140 and the third support 150 may be a first distance L1 based on the second body portion 140A and the third body portion 150A, and may be a second distance L2 less than the first distance L1 based on the second protrusion 140B and the third protrusion 150B. In addition, referring to FIG. 1D, a thickness of the first/fourth supports 130 and 160 may be increased compared to a case where only the first/fourth body portions 130A and 160A exist. In addition, a distance between the first support 130 and the fourth support 160 may be a third distance L3 based on the first body portion 130A and the fourth body portion 160A, and may be a fourth distance L4 less than the third distance L3 based on the first protrusion 130B and the fourth protrusion 160B. Therefore, in an embodiment, support force of the first, second, third, and fourth supports 130, 140, 150, and 160 may be improved at the boundary between the first region R1 and the second region R2, and bending of the gate structure 110G and the stack 110S may be prevented or reduced.

The slit structures 190 may extend through the gate structure 110G. At least one of the slit structures 190 may extend from the first region R1 to the second region R2. The slit structures 190 may include an insulating material, a conductive material, and/or a semiconductor material.

According to an embodiment of the structure described above, the semiconductor device may include the first/third supports 130 and 150 positioned in the first region R1 and may include the first/third protrusions 130B and 150B protruding toward the second region R2. The second/fourth supports 140 and 160 positioned in the second region R2 may include the second/fourth protrusions 140B and 150B protruding toward the first region R1. In this case, in an embodiment, support force of the first, second, third, and fourth supports 130, 140, 150, and 160 may be improved near the boundary surface between the first region R1 and the second region R2 where support force of the first, second, third, and fourth supports 130, 140, 150, and 160 may be weakened.

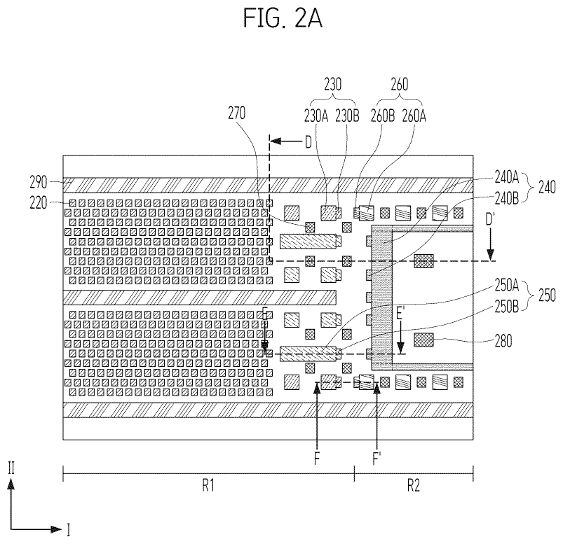

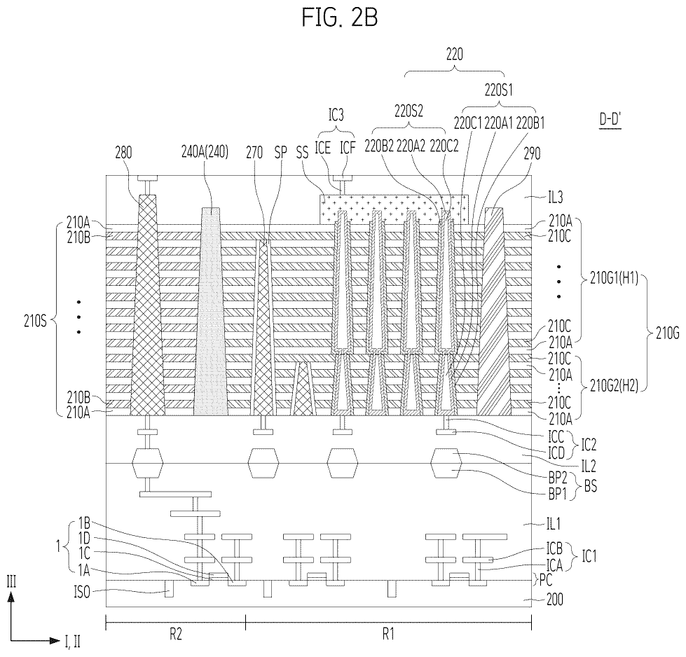

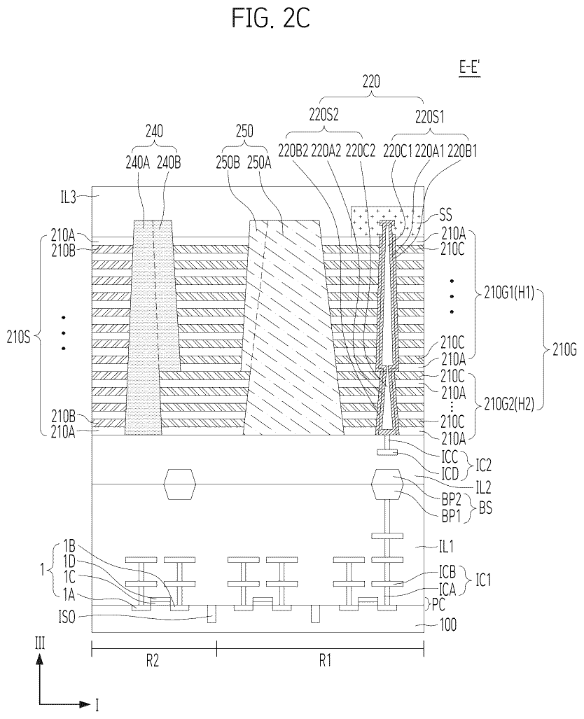

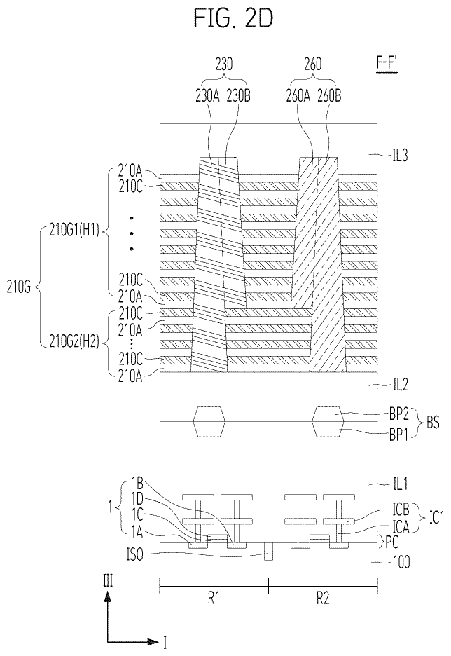

FIGS. 2A to 2D are drawings illustrating a semiconductor device according to an embodiment of the present disclosure. FIG. 2A is a plan view, FIG. 2B is a cross-sectional view taken along line D-D′ of FIG. 2A, FIG. 2C is a cross-sectional view taken along line E-E′ of FIG. 2A. and FIG. 2D is a cross-sectional view taken along line F-F′ of FIG. 2A. Hereinafter, a content that overlaps with the content described above is omitted.

Referring to FIGS. 2A to 2D, the semiconductor device may include a substrate 200, a peripheral circuit PC, a stack 210S, a gate structure 210G, channel structures 220, first supports 230, a second support 240, third supports 250, fourth supports 260, contact vias 270, contact plugs 280, slit structures 290, a first interlayer insulating layer IL1, a second interlayer insulating layer IL2, a first interconnection structure IC1, a second interconnection structure IC2, an element isolation layer ISO, a source structure SS, an insulating spacer SP, and a bonding structure BS.

The substrate 200 may include a first region R1 and a second region R2. The first region R1 and the second region R2 may be adjacent to each other in a first direction I. The first region R1 may be a region where memory cells are positioned, and may be a region where the contact vias 270 respectively connected to conductive layers 210C of the gate structure 210G are positioned. The second region R2 may be a region where the contact plugs 280 electrically connected to the peripheral circuit PC are positioned, and may be a region where the contact vias 270 are positioned.

The peripheral circuit PC may be positioned on the substrate 200. For example, the peripheral circuit PC may be positioned in the second region R2. However, the present disclosure is not limited thereto, and the peripheral circuit PC may be positioned in the first region R1 and the second region R2. A transistor 1 may include junctions 1A and 1B, a gate electrode 1D, and a gate insulating layer 1C.

The first interconnection structure IC1 may be positioned on the peripheral circuit PC. The first interconnection structure IC1 may be positioned in the first interlayer insulating layer IL1. Here, the first interlayer insulating layer IL may be positioned on the substrate 200. The first interconnection structure IC1 may include first vias ICA and first lines ICB.

The bonding structures BS may be positioned on the first interconnection structure IC1. The bonding structures BS may be positioned in the first region R1 and the second region R2. The bonding structure BS may include a first bonding pad BP1 and a second bonding pad BP2. The first bonding pad BP1 may be positioned in the first interlayer insulating layer IL1. The second bonding pad BP2 may be positioned in the second interlayer insulating layer IL2. Here, the second interlayer insulating layer IL2 may be positioned on the first interlayer insulating layer IL1.

The gate structure 210G may be positioned over the substrate 200. The gate structure 210G may extend from the first region R1 to the second region R2. The gate structure 210G may include first insulating layers 210A and conductive layers 210C alternately stacked. The gate structure 210G may include a first portion 210G1 and a second portion 210G2 positioned on the first portion 210G1. For example, the gate structure 210G may include the first portion 210G1 having a first height H1 and the second portion 210G2 having a second height H2. Here, the first height H1 and the second height H2 may be substantially equal to each other or different from each other. For example, the second height H2 may be less than the first height H1. The conductive layers 210C may include a conductive material such as tungsten, molybdenum, or polysilicon.

The stack 210S may be positioned over the substrate 200. The stack 210S may be positioned in the second region R2. The stack 210S may include first insulating layers 210A and second insulating layers 210B alternately stacked. The first insulating layers 210A may include an insulating material such as an oxide, and the second insulating layers 210B may include a sacrificial material such as a nitride.

The channel structures 220 may be positioned in the first region R1 and may extend through the gate structure 210G. For example, the channel structures 220 may extend into the source structure SS through the gate structure 210G. Here, the source structure SS may be positioned on the channel structures 220. Each of the channel structures 220 may include a first sub-channel structure 220S1 and a second sub-channel structure 220S2. For example, the channel structure 220 may include the first sub-channel structure 220S1 extending through the first portion 210G1, and may include the second sub-channel structure 220S2 extending through the second portion 220S2 and connected to the first sub-channel structure 220S1. The first sub-channel structure 220S1 may include a first sub-channel layer 220A1, a first sub-memory layer 220B1 surrounding the first sub-channel layer 220A1, and a first sub-insulating core 220C1 in the first sub-channel layer 220A1. Here, the first sub-channel layer 220A1 of the first sub-channel structure 220S1 may be connected to the source structure SS. The second sub-channel structure 220S2 may include a second sub-channel layer 220A2, a second sub-memory layer 220B2, and a second sub-insulating core 220C2 in the second sub-channel layer 220A2.

The second interconnection structure IC2 may be positioned on the bonding structure BS. The second interconnection structure IC2 may be positioned in the second interlayer insulating layer IL2. The second interconnection structure IC2 may include second vias ICC and second lines ICD. The contact plug 280 may be electrically connected to the peripheral circuit PC through the second interconnection structure IC2, the bonding structure BS, and the first interconnection structure IC1. For reference, although not shown in this drawing, the channel structures 220 and/or the contact vias 270 may be electrically connected to the peripheral circuit PC through the second interconnection structure IC2, the bonding structure BS, and the first interconnection structure IC1.

The first supports 230 may be positioned in the first region R1 and may extend through the gate structure 210G. The first supports 230 may be successively arranged in the first direction I. At least one of the first supports 230 may include a first body portion 230A and a first protrusion 230B. Here, the first body portion 230A may extend through the gate structure 210G, and the first protrusion 230B may protrude from the first body portion 230A in the gate structure 210G. The first protrusion 230B may protrude toward the second support 240. For example, the first protrusion 230B may protrude toward the second region R2. The first protrusion 230B may be positioned at a level corresponding to the first portion 210G1. For example, the first protrusion 230B may be positioned at a level corresponding to the first sub-channel structure 220S1. The first supports 230 may include an insulating material such as an oxide.

The second support 240 may be positioned in the second region R2 and may extend between the gate structure 210G and the stack 210S. The second support 240 may extend in a second direction II. The second support 240 may include a second body portion 240A and a second protrusion 240B. Here, the number of second protrusions 240B may be plural. The second body portion 240A may extend between the gate structure 210G and the stack 210S. The second protrusion 240B may protrude from the second body portion 240A in the gate structure 210G. The second protrusion 240B may protrude toward the first supports 230. For example, the second protrusion 240B may protrude toward the first region R1. The second protrusion 240B may be positioned at a level corresponding to the first portion 210G1. For example, the second protrusion 240B may be positioned at a level corresponding to the first sub-channel structure 220S1. The second supports 240 may include an insulating material such as an oxide.

The third supports 250 may be positioned in the first region R1 and may extend through the gate structure 210G. The third supports 250 may extend in the first direction I. At least one of the third supports 250 may include a third body portion 250A and/or a third protrusion 250B. Here, the third body portion 250A may extend through the gate structure 210G, and the third protrusion 250B may protrude toward the second region R2 in the gate structure 210G. The third protrusion 250B may be positioned at a level corresponding to the first sub-channel structure 220S1. The third supports 250 may include an insulating material such as an oxide.

The fourth supports 260 may be positioned in the second region R2 and may extend through the gate structure 210G. The fourth supports 260 may be successively arranged in the first direction I. At least one of the fourth supports 260 may include a fourth body portion 260A and/or a fourth protrusion 260B. Here, the fourth body portion 260A may extend through the gate structure 210G, and the fourth protrusion 260B may protrude toward the first region R1 in the gate structure 210G. The fourth protrusion 260B may be positioned at a level corresponding to the first sub-channel structure 220S1. The fourth supports 260 may include an insulating material such as an oxide.

The contact vias 270 may extend through the gate structure 210G and may be respectively connected to the conductive layers 210C. Here, the insulating spacers SP may surround a sidewall of the contact vias 270. The contact vias 270 may be positioned in the first region R1 and the second region R2. For example, the contact vias 270 may be positioned between the first supports 230 and the third support 250, between the third supports 260, and/or between the first/third supports 230 and 150 and the second support 240. The insulating spacers SP may include an insulating material such as an oxide, and the contact vias 270 may include a conductive material such as tungsten.

The contact plug 280 may be positioned in the second region R2 and may extend through the stack 210S. For example, the contact plug 280 may extend through the stack 210S and may be electrically connected to the peripheral circuit PC. The contact plugs 280 may include a conductive material such as tungsten.

According to an embodiment of the present disclosure, the first and third protrusions 230B and 250B protruding from the first region R1 toward the second region R2 may be included, and the second and fourth protrusions 240B and 260B protruding from the second region R2 toward the first region R1 may be included. In this case, compared to a case where the first, second, third, and fourth protrusions 230B, 240B, 250B, and 260B do not exist, a thickness of the first, second, third, and fourth supports 230, 240, 250, and 260 may be increased, a distance between the first/third supports 230 and 250 and the second/fourth supports 240 and 260 may become relatively shorter, and thus, in an embodiment, support force of the first, second, third, and fourth supports 230, 240, 250, may 260 may be improved.

The slit structures 290 may extend through the gate structure 210G. At least one of the slit structures 290 may extend from the first region R1 to the second region R2. The slit structures 290 may include an insulating material, a conductive material, and/or a semiconductor material.

According to the structure described above, the semiconductor device may include the bonding structure BS. The bonding structure BS may be positioned on the peripheral circuit PC and may be electrically connected to the peripheral circuit PC. Therefore, the channel structures 220, the contact vias 270, and/or the contact plugs 280 may be electrically connected to the peripheral circuit PC through the bonding structure BS.

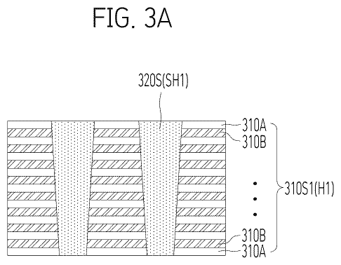

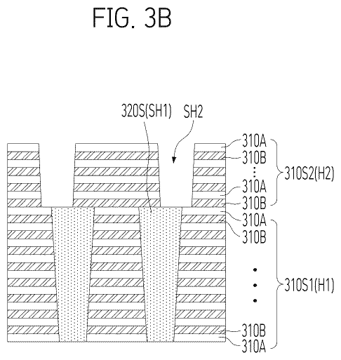

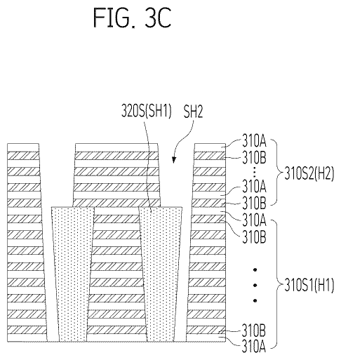

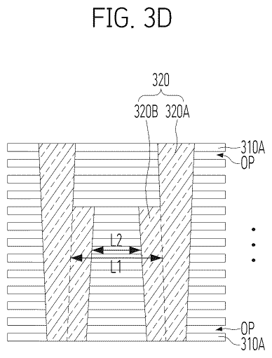

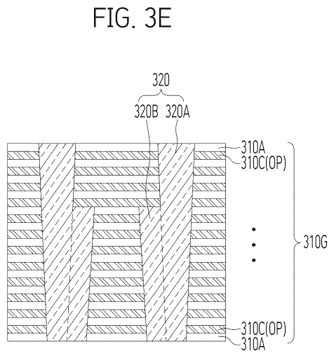

FIGS. 3A to 3E are drawings illustrating a method of manufacturing a semiconductor device according to an embodiment of the present disclosure. Hereinafter, a content that overlaps with the content described above is omitted.

Referring to FIG. 3A, a first sub-stack 310S1 may be formed. For example, first material layers 310A and second material layers 310B may be alternately stacked to form the first sub-stack 310S1. Here, the first sub-stack 310S1 may have a first height H1. The first material layers 310A and the second material layers 310B may include different materials. For example, the first material layers 310A may include an insulating material such as an oxide, and the second material layers 310B may include a sacrificial material such as a nitride.

Subsequently, a first support hole SH1 extending through the first sub-stack 310S1 may be formed. Here, the first support hole SH1 may be formed using a plasma process. For example, the first support hole SH1 may be formed by etching the first sub-stack 310S1 using plasma. However, the present disclosure is not limited thereto, and the first support hole SH1 may be formed in various methods. Subsequently, a support sacrificial layer 320S may be formed in the first support hole SH1. Here, the support sacrificial layer 320S may include a sacrificial material such as a metal material. For example, the support sacrificial layer 320S may include titanium nitride, tungsten, or the like.

Referring to FIG. 3B, a second sub-stack 310S2 may be formed on the first sub-stack 310S1. For example, first material layers 310A and second material layers 310B may be alternately stacked on the first sub-stack 310S1 to form the second sub-stack 310S2. Here, the second sub-stack 310S2 may have a second height H2. The second height H2 may be substantially equal to or different from the first height H1. For example, the second height H2 may be less than the first height H1.

Subsequently, a second support hole SH2 extending through the second sub-stack 310S2 may be formed. For example, the second support hole SH2 exposing the support sacrificial layer 320S through the second sub-stack 310S2 may be formed. Here, the second support hole SH2 may be formed so that a center of the first support hole SH1 and a center of the second support hole SH2 are misaligned. In this case, the second support hole SH2 may expose a portion of an upper surface of the support sacrificial layer 320S.

According to an embodiment of the present disclosure, the second height H2 of the second sub-stack 310S2 may be less than the first height H1 of the first sub-stack 310S1. In other words, the second sub-stack 310S2 may be formed with a relatively small height. In this case, in an embodiment, when the second support hole SH2 is formed so that the center of the first support hole SH1 and the center of the second support hole SH2 are misaligned, the second support hole SH2 may be formed more accurately at a desired position.

Referring to FIG. 3C, the second support hole SH2 may extend. For example, the second support hole SH2 extending through the first sub-stack 310S1 and exposing a sidewall of the support sacrificial layer 320S may be formed. Here, the second support hole SH2 may extend along a profile of the support sacrificial layer 320S.

The second support hole SH2 may be formed using a plasma process. For example, the second support hole SH2 may be formed by etching the second sub-stack 310S2 and the first sub-stack 310S1 using plasma. Because the support sacrificial layer 320S may include a metal material, ions in the plasma may be attracted to the metal material in a process of forming the second support hole SH2, and the second support hole SH2 may be formed along the profile of the support sacrificial layer 320S. Therefore, the second support hole SH2 may extend along the sidewall of the support sacrificial layer 320S.

For reference, when the second support hole SH2 is formed without forming the support sacrificial layer 320S, the second support hole SH2 may be formed in a taper shape of which a width is regularly decreased from an upper portion to a lower portion. However, when forming the support sacrificial layer 320S and forming the second support hole SH2, the second support hole SH2 may be formed along the sidewall of the support sacrificial layer 320S. In other words, the second support hole SH2 may be formed in a direction parallel to the sidewall of the support sacrificial layer 320S. Therefore, the shape of the second support hole SH2 when the support sacrificial layer 320S is not formed and the shape of the second support hole SH2 when the support sacrificial layer 320S is formed may be different from each other.

Referring to FIG. 3D, the support sacrificial layer 320S may be removed through the second support hole SH2. Subsequently, a support 320 may be formed in the second support hole SH2 and the first support hole SH1. In this case, each of the supports 320 may include a body portion 320A and a protrusion 320B protruding from the body portion 320A. Here, the protrusion parts 320B may respectively protrude toward different supports 320. The support 320 may include an insulating material such as an oxide.

Subsequently, the second material layers 310B may be removed to form openings OP. For example, the second material layers 310B of the first sub-stack 310S1 and the second sub-stack 310S2 may be removed to form the openings OP. Here, in an embodiment, when support force of the supports 320 is weak, the first sub-stack 310S1 and the second sub-stack 310S2 may be bent. In an embodiment, this problem may be aggravated as a height of the first sub-stack 310S1 and the second sub-stack 310S2 increases.

According to an embodiment of the present disclosure, the supports 320 may form the protrusions 320B compared to a case where only the body portions 320A are formed, and thus a thickness of a lower portion including the protrusions 320B may be greater than a thickness of an upper portion that does not includes the protrusions 320B. Through this, in an embodiment, support force of the supports 320 may be improved.

In addition, a distance between the supports 320 may be a first distance L1 based on the body portions 320A, and a second distance L2 less than the first distance L1 based on the protrusions 320B. In an embodiment, the distance between the supports 320 is decreased, support force of the supports 320 may be improved. Therefore, in an embodiment, by forming the protrusions 320B, bending of the first sub-stack 31051 and the second sub-stack 31052 may be prevented or reduced.

Referring to FIG. 3E, third material layers 310C may be formed in the openings OP. Accordingly, a gate structure 310G in which the first material layers 310A and the third material layers 310C are alternately stacked may be formed. Here, the third material layers 310C may include a conductive material such as tungsten.

For reference, although not shown in this drawing, an additional support sacrificial layer may be formed in the second sub-stack 31052 before forming the second support hole SH2. The additional support sacrificial layer in the second sub-stack 31052 may be formed to be connected to the support sacrificial layer 320S in the first sub-stack 31051. Subsequently, the second support hole SH2 may be formed along the additional support sacrificial layer and the support sacrificial layer 320S. In this case, the supports may include an additional protrusion not only in the first sub-stack but also in the second sub-stack. Therefore, in an embodiment, because both a lower portion thickness and an upper portion thickness of the supports may be increased, support force of the supports may be improved.

According to the manufacturing method described above, the plasma process may be used in a process of forming the second support hole SH2. In this case, the second support hole SH2 may be formed along a profile of the support sacrificial layer 320S including a metal material. Subsequently, the support sacrificial layer 320S may be removed through the second support hole SH2 to form the support 320. Here, in an embodiment, a region where the support sacrificial layer 320S is formed may configure the protrusion 320B of the support 320, and support force of the support 320 may be improved.

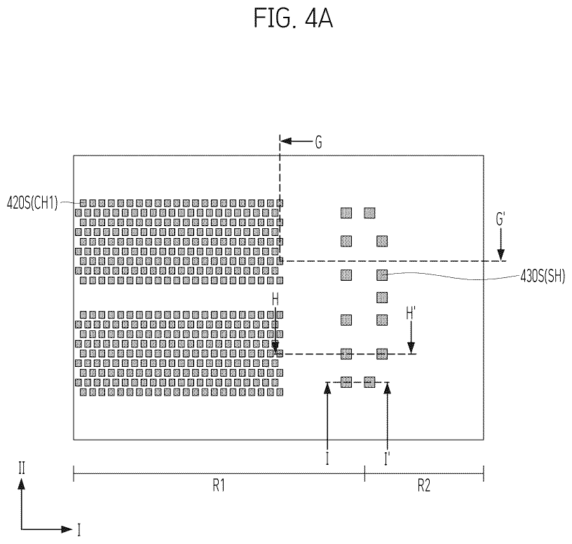

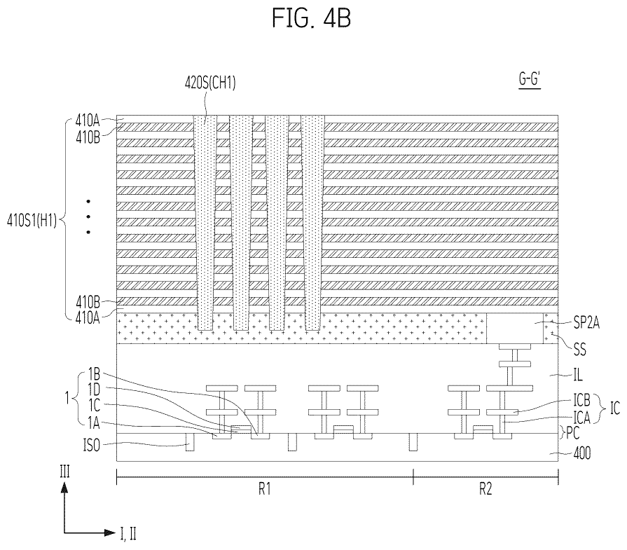

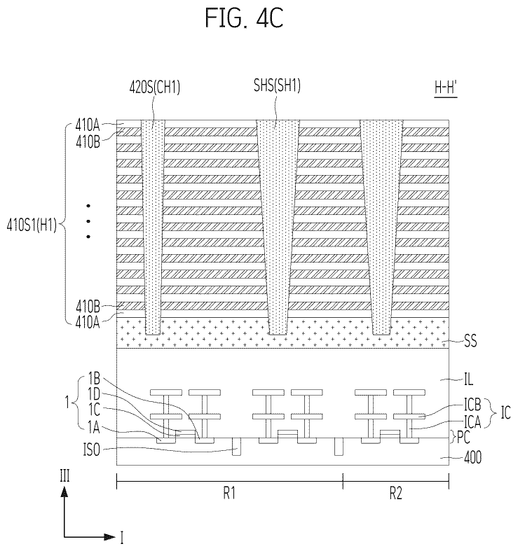

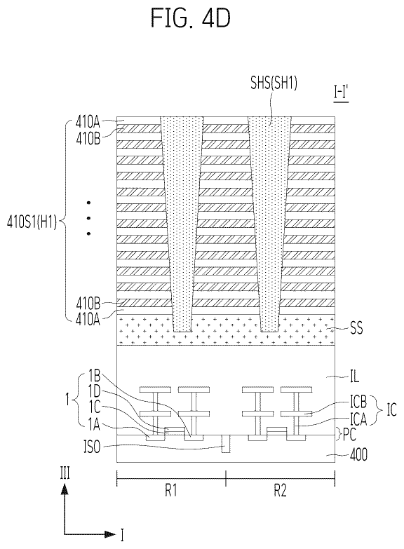

FIGS. 4A to 4D, 5A to 5D, 6A to 6D, 7A to 7D, and 8A to 8D are drawings illustrating a method of manufacturing a semiconductor device according to an embodiment of the present disclosure. Hereinafter, a content that overlaps with the content described above is omitted.

Referring to FIGS. 4A to 4D, a peripheral circuit PC may be formed on a substrate 400 including a first region R1 and a second region R2. Here, the first region R1 and the second region R2 may be adjacent to each other in a first direction I. The first region R1 may be a region where memory cells are formed. The second region R2 may be a region where contact plugs electrically connected to the peripheral circuit PC are formed. Contact vias respectively connected to conductive layers of a gate structure may be formed in the first region R1 and the second region R2.

The peripheral circuit PC may be formed in the second region R2. However, the present disclosure is not limited thereto, and the peripheral circuit PC may be formed in the first region R1 and the second region R2. The peripheral circuit PC may include a transistor 1, a capacitor, and the like. The transistor 1 may include junctions 1A and 1B, a gate electrode 1D, and a gate insulating layer 1C. Here, the gate insulating layer 1C may be formed between the gate electrode 1D and the substrate 400. An element isolation layer ISO may be formed in the substrate 400, an active region may be defined by the element isolation layer ISO, and the transistor 1 may be positioned in the active region.

Subsequently, an interconnection structure IC may be formed on the peripheral circuit PC. The interconnection structure IC may be formed in an interlayer insulating layer IL. Here, the interlayer insulating layer IL may be formed on the substrate 400. The interconnection structure IC may include vias ICA and lines ICB.

The interconnection structure IC may be connected to the peripheral circuit PC. For example, at least one of the vias ICA may be connected to the transistor 1. At least one of the vias ICA may interconnect the lines ICB. The lines ICB may interconnect the vias ICA. The interconnection structure IC may include a conductive material such as tungsten. The interlayer insulating layer IL may include an insulating material such as an oxide.

Subsequently, a source structure SS may be formed on the interconnection structure IC. The source structure SS may be formed as a single layer or multiple layers. The source structure SS may include a conductive material such as polysilicon, and may include an insulating material such as an oxide.

Subsequently, a preliminary second insulating spacer SP2A may be formed in the source structure SS. The preliminary second insulating spacer SP2A may be formed in a region where contact plugs are to be formed. For example, the preliminary second insulating spacer SP2A may be formed in the second region R2. The preliminary second insulating spacer SP2A may include an insulating material such as an oxide.

Subsequently, a first sub-stack 410S1 may be formed on the source structure SS. For example, first material layers 410A and second material layers 410B may be alternately stacked to form the first sub-stack 410S1. Here, the first sub-stack 410S1 may be formed with a first height H1. The first material layers 410A may include an insulating material such as an oxide. The second material layers 410B may include a sacrificial material such as a nitride.

Subsequently, a first channel hole CH1 extending through the first sub-stack 410S1 may be formed. For example, the first channel hole CH1 extending into the source structure SS through the first sub-stack 410S1 may be formed. The first channel holes CH1 may be formed in the first region R1.

First support holes SH1 extending through the first sub-stack 410S1 may be formed. For example, the first support holes SH1 extending into the source structure SS through the first sub-stack 410S1 may be formed. The first support holes SH1 may be formed in the first region R1 and the second region R2. For example, the first support holes SH1 may be formed near a boundary between the first region R1 and the second region R2. When forming the first channel hole CH1, the first support hole SH1 may be formed. However, the present disclosure is not limited thereto, and the first channel hole CH1 and the first support hole SH1 may be formed at different times.

Subsequently, a channel sacrificial layer 420S may be formed in the first channel hole CH1. A support sacrificial layer SHS may be formed in the first support hole SH1. When forming the channel sacrificial layer 420S, the support sacrificial layer SHS may be formed. However, the present disclosure is not limited thereto, and the channel sacrificial layer 420S and the support sacrificial layer SHS may be formed in separate processes. At least one of the channel sacrificial layer 420S or the support sacrificial layer SHS may include a metal material. For example, at least one of the channel sacrificial layer 420S or the support sacrificial layer SHS may include at least one of titanium nitride or tungsten.

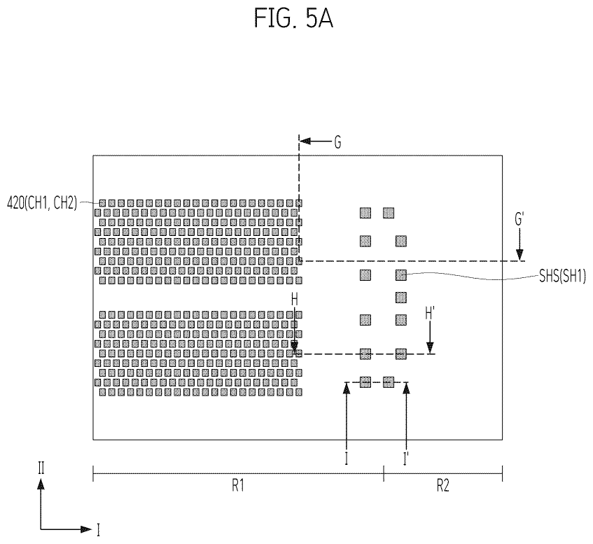

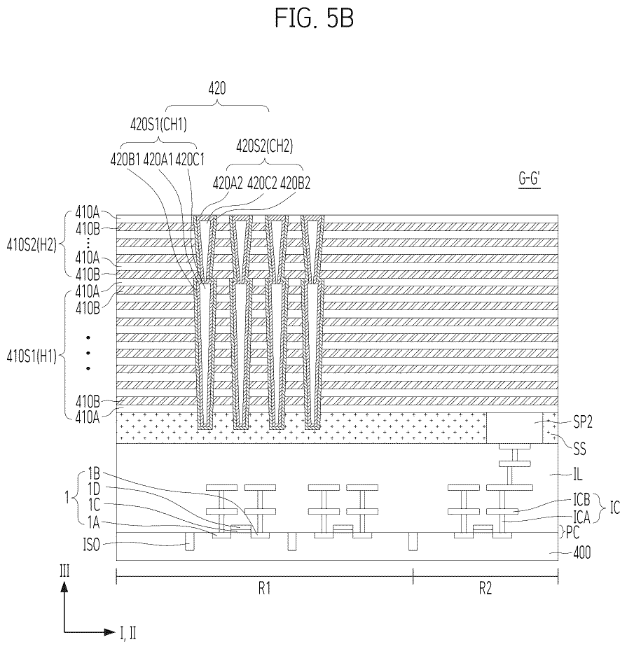

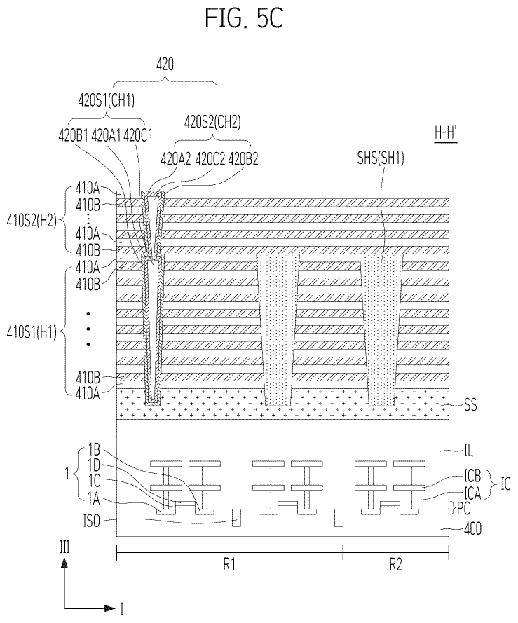

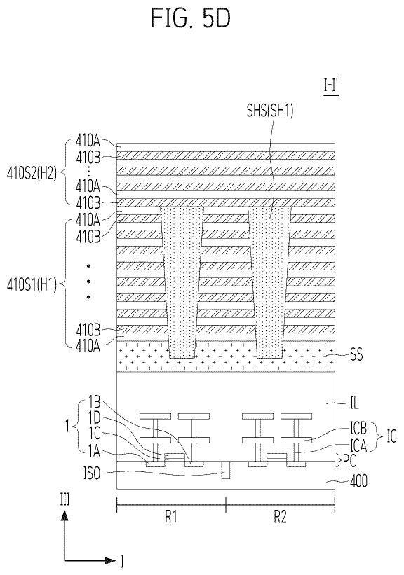

Referring to FIGS. 5A to 5D, a second sub-stack 420S2 may be formed on the first sub-stack 410S1. For example, first material layers 410A and second material layers 410B may be alternately stacked on the first sub-stack 410S1 to form the second sub-stack 410S2. Here, the second sub-stack 410S1 may be formed with a second height H2 less than the first height H1.

Subsequently, a second channel hole CH2 extending through the second sub-stack 410S2 may be formed. For example, the second channel hole CH2 exposing the channel sacrificial layer 420S through the second sub-stack 410S2 may be formed.

Subsequently, the channel sacrificial layer 420S may be removed through the second channel hole CH2. Subsequently, a channel structure 420 may be formed in the first channel hole CH1 and the second channel hole CH2. For example, the channel structure 420, which includes a first sub-channel structure 420S1 including a first sub-channel layer 420A1, a first sub-memory layer 420B1, and a first sub-Insulating core 420C1 formed in the first channel hole CH1, and a second sub-channel structure 420S2 including a second sub-channel layer 420A2, a second sub-memory layer 420B2, and a second sub-insulating core 420C2 formed in the second channel hole CH2 may be formed.

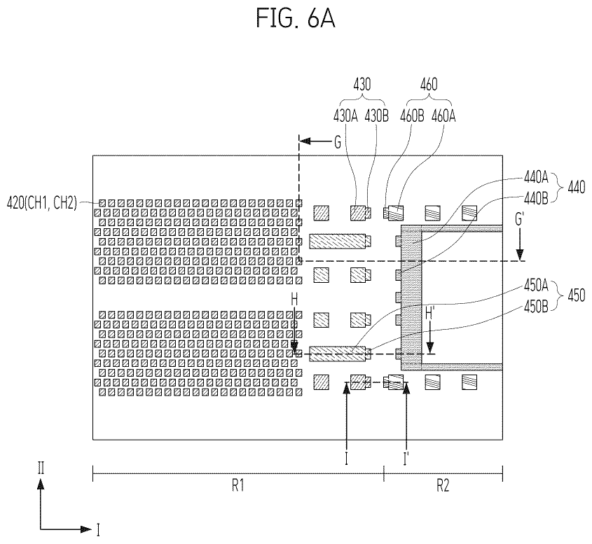

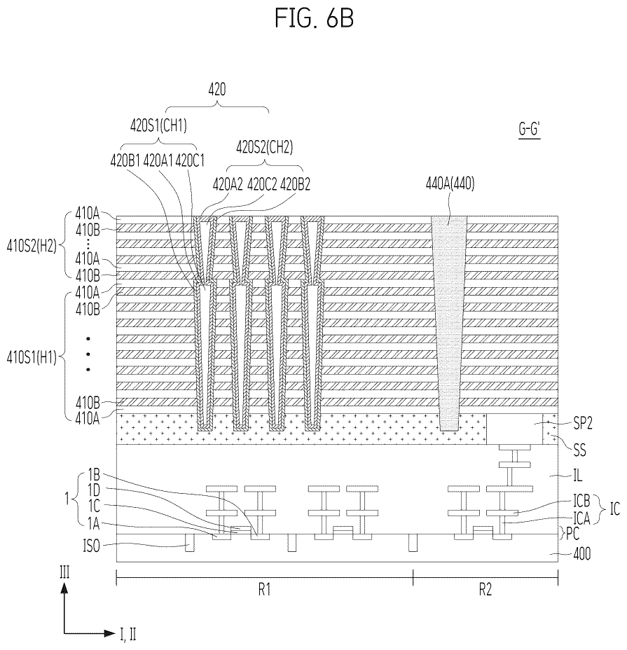

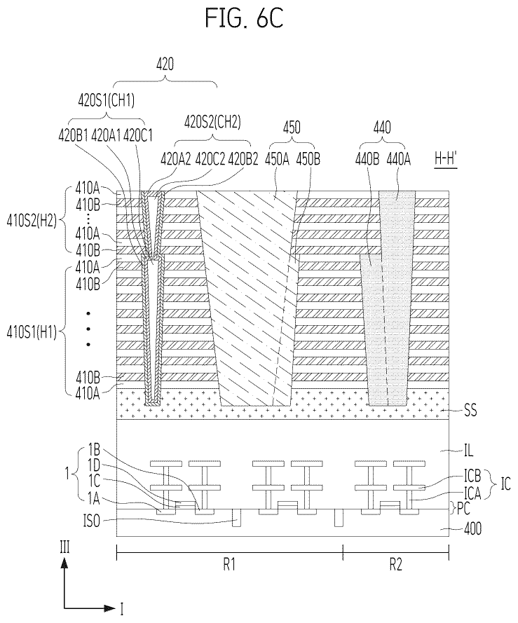

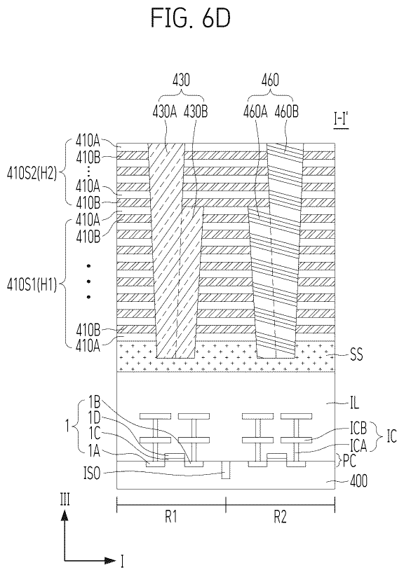

Referring to FIGS. 6A to 6D, first supports 430 and third supports 450 may be formed in the first region R1, and second supports 440 and fourth supports 460 may be formed in the second region R2.

The first supports 430 may be formed to be successively arranged in the first direction I. The first supports 430 may include a first body portion 430A and/or a first protrusion 430B. For example, at least one of the first supports 430 may include a first body portion 430A and a first protrusion 430B. Here, the first body portion 430A may extend through the first sub-stack 410S1 and the second sub-stack 410S2, and the first protrusion 430B may protrude from the first body portion 430A in the first sub-stack 410S1. The first protrusion 430B may protrude toward the second region R2.

The second support 440 may extend in a second direction II intersecting the first direction I. The second support 440 may include a second body portion 440A and a second protrusion 440B. Here, the number of second protrusions 440B may be plural. The second body portion 440 may extend through the first sub-stack 410S1 and the second sub-stack 410S2. The second body portion 440A may include first extensions extending in the first direction I and second extensions extending in the second direction II, and the first extensions may be interconnected by the second extension. The second protrusion 440B may protrude from the second body portion 440A in the first sub-stack 410S1. The second protrusion 140B may protrude toward the first region R1.

The third supports 450 may extend in the first direction I. At least one of the third supports 450 may include a third body portion 450A and/or a third protrusion 450B. Here, the third body portion 450A may extend through the first sub-stack 410S1 and the second sub-stack 410S2, and the third protrusion 450B may protrude toward the second region R2 in the first sub-stack 410S1.

The fourth supports 460 may be successively arranged in the first direction I. At least one of the fourth supports 460 may include a fourth body portion 460A and/or a fourth protrusion 460B. Here, the fourth body portion 160A may extend through the first sub-stack 410S1 and the second sub-stack 410S2, and the fourth protrusion 160B may protrude toward the first region R1 in the first sub-stack 410S1. The first, second, third, and fourth supports 430, 440, 450, and 460 may include an insulating material such as an oxide.

Here, the first, second, third, and fourth supports 430, 440, 450, and 460 including the protrusions 430B, 440B, 450B, and 460B among the first, second, third, and fourth supports 430, 440, 450, and 460 may be formed in a method identical to/similar to that of FIGS. 3A to 3E. First, second support holes exposing a sidewall of the support sacrificial layers SHS formed in the first region R1 and the second region R2 may be formed. Subsequently, the support sacrificial layers SHS may be removed through the second support holes. Subsequently, the first, second, third, and fourth supports 430, 440, 450, and 460 including protrusions 430B, 440B, 450B, and 460B among the first, second, third, and fourth supports 430, 440, 450, and 460 may be formed in the first support holes SH1 and second support holes SH2.

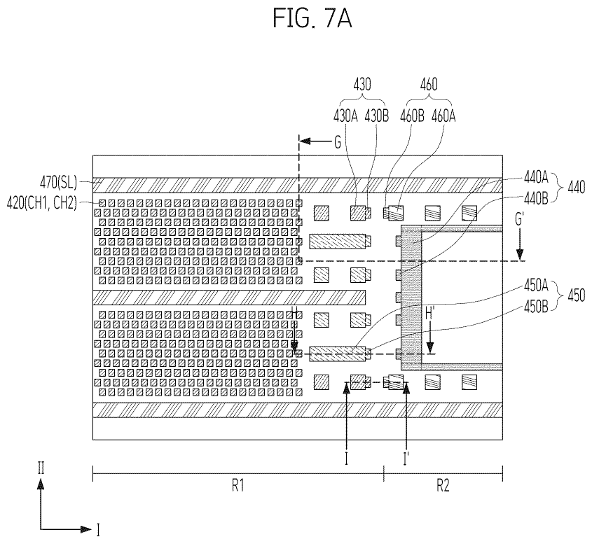

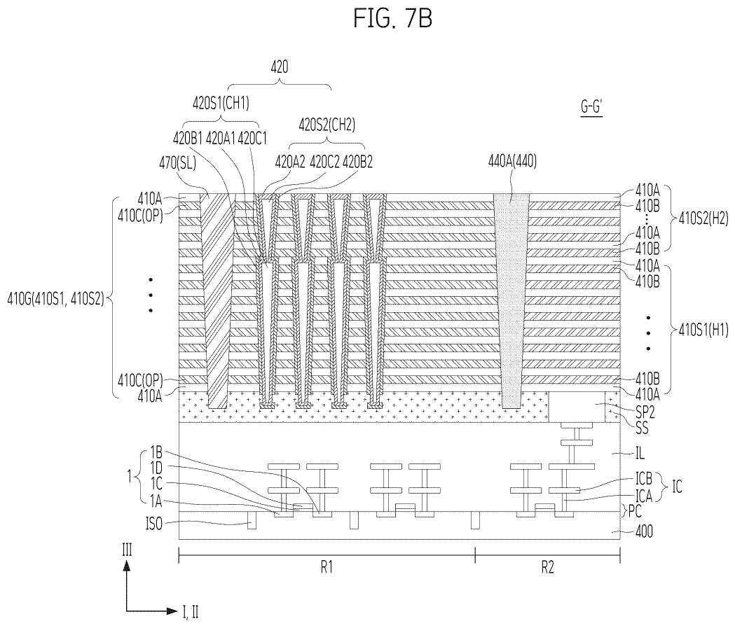

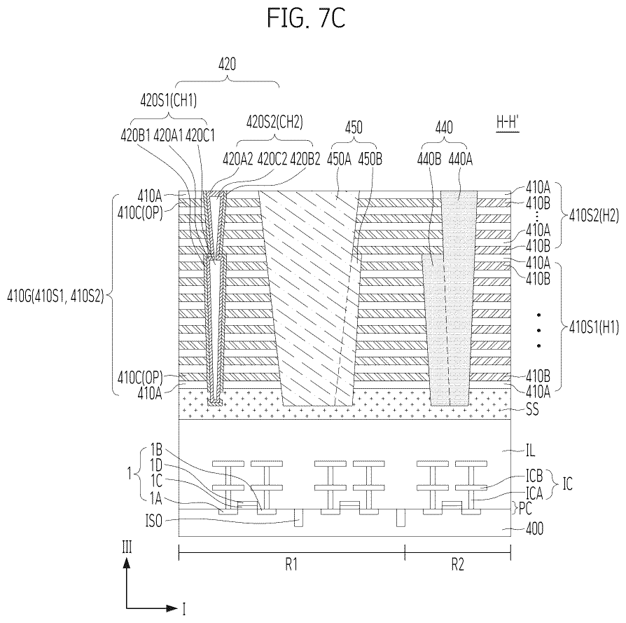

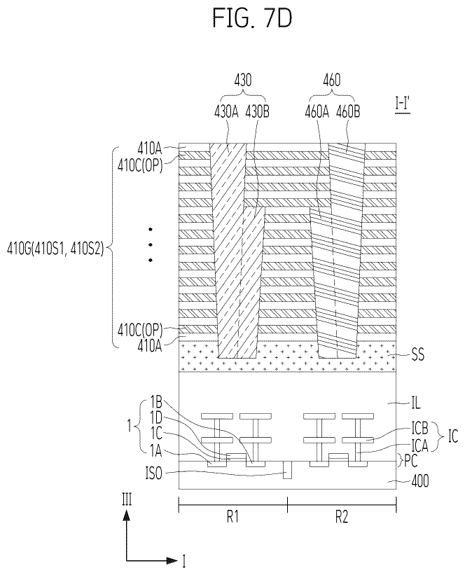

Referring to FIGS. 7A to 7D, slits SL extending in the first direction I may be formed. The slits SL extending through the first sub-stack 410S1 and the second sub-stack 410S2 may be formed.

For reference, although not shown in the drawing, a portion of the source structure SS may be removed to form a source opening so that the first sub-channel structure 420S1 is exposed through the slits SL. Subsequently, a portion of the first sub-memory layer 420B1 may be removed through the source opening so that the first sub-channel layer 420A1 is exposed. Subsequently, a semiconductor material and the like may be formed in the source opening. Accordingly, the first sub-channel layers 420A1 of the channel structures 420 may be connected to the source structure SS.

Subsequently, the second material layers 410B of the first sub-stack 410S1 and the second material layers 410B of the second sub-stack 410S2 may be removed through the slits SL to form openings OP.

Subsequently, third material layers 410C may be formed in the openings OP to form a gate structure 410G. Accordingly, the gate structure 410G including the first material layers 410A and the third material layers 410C alternately stacked may be formed. However, the present disclosure is not limited thereto, and when the second material layers 410B of the first sub-stack 410S1 and the second sub-stack 410S2 include a conductive material, a process of replacing the second material layers 410B with the third material layers 410C may be omitted. In this case, the first sub-stack 410S1 and the second sub-stack 410S2 may be used as the gate structure 410G. Here, the third material layers 410C may be a gate line such as a source selection line, a word line, and a drain selection line as a conductive layer.

A portion of the first sub-stack 410S1 and the second sub-stack 410S2 may remain without being replaced with the gate structure 410G. For example, the first sub-stack 410S1 and the second sub-stack 410S2 surrounded by the second support 440 may remain without being replaced with the gate structure 410G.

Subsequently, slit structures 470 may be formed in the slit SL. The slit structures 190 may include an insulating material, a conductive material, and/or a semiconductor material.

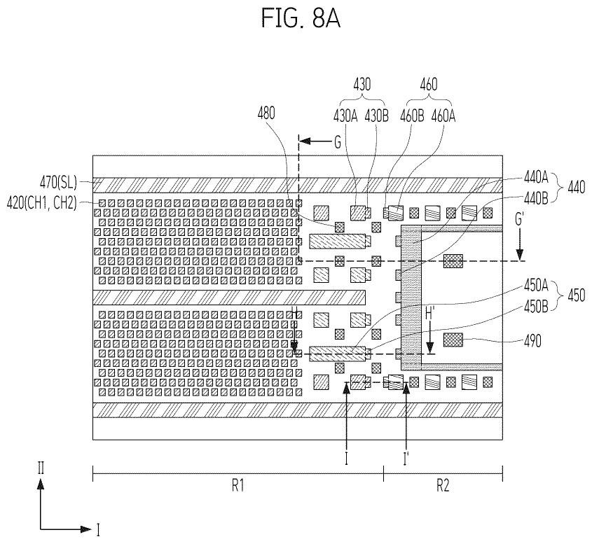

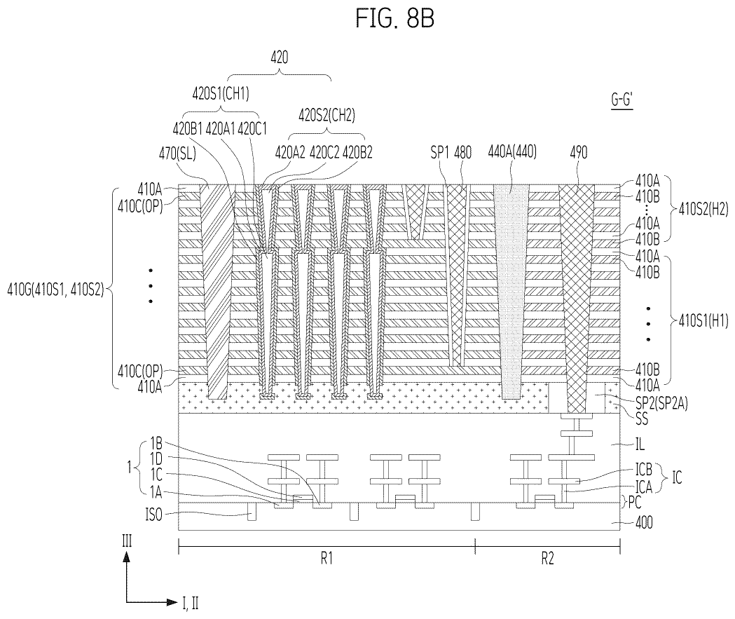

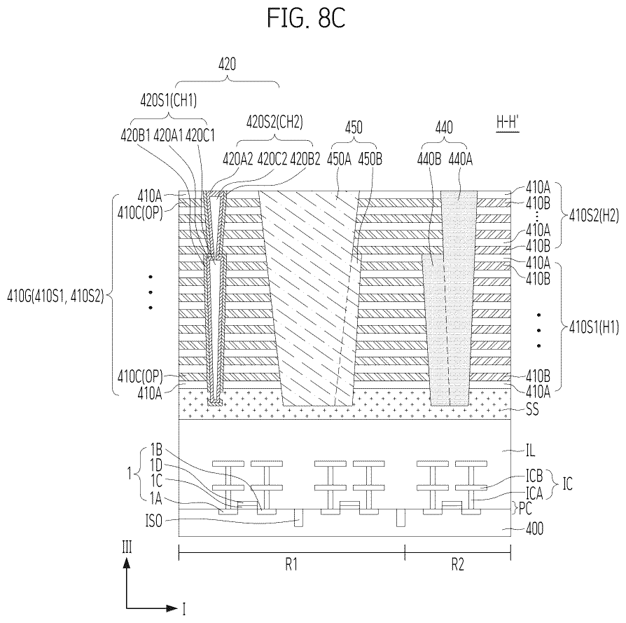

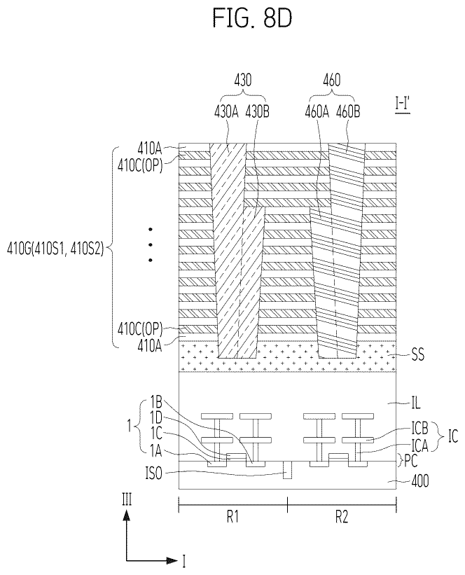

Referring to FIGS. 8A to 8D, contact vias 480 and contact plugs 490 may be formed. For example, the contact vias may be formed in the first region R1 and the second region R2, and the contact plugs 490 may be formed in the second region R2. The contact vias 480 may be formed between the first supports 430 and the third support 450, between the third supports 450, and/or between the first/third supports 430 and 450 and the second support 440. The contact plugs 490 may be formed in a region surrounded by the second support 440.

The contact vias 480 may extend through the gate structure 410G and may be respectively connected to the third material layers 410C. Here, a side surface of the contact vias 480 may be surrounded by the first insulating spacers SP1. The first insulating spacers SP1 may include an insulating material such as an oxide, and the contact vias 480 may include a conductive material such as tungsten.

The contact plugs 490 may extend through the first sub-stack 410S1 and the second sub-stack 410S2 and may be electrically connected to the peripheral circuit PC. For example, the contact plugs 490 may pass through the source structure SS through the first sub-stack 410S1 and the second sub-stack 410S2, and may be electrically connected to the peripheral circuit PC through the interconnection structure IC. At this time, the preliminary second insulating spacer SP2A may be separated into the second insulating spacers SP2. The contact plugs 490 may include a conductive material such as tungsten.

According to the manufacturing method described above, the first and third supports 430 and 450 including the first and third protrusions 430B and 450B protruding from the first region R1 toward the second region R2 may be formed, and the second and fourth supports 440 and 460 including the second and fourth protrusions 440B and 460B protruding from the second region R2 toward the first region R1 may be formed.

In this case, in an embodiment, compared to a case where the first, second, third, and fourth protrusions 430B, 440B, 450B, and 460B are not formed, a thickness of a lower portion of the first, second, third, and fourth supports 430, 440, 450, and 460 may be increased, a distance between the first/third supports 430 and 450 and the second/fourth supports 440 and 460 may become relatively shorter, and thus support force of the first, second, third, and fourth supports 430, 440, 450, and 460 may be improved.

Although embodiments according to the technical spirit of the present disclosure have been described with reference to the accompanying drawings, this is only for describing an embodiment according to the concept of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a substrate including a first region and a second region;
a gate structure positioned over the substrate and extending from the first region to the second region;
a stack positioned in the second region over the substrate;
first supports extending through the gate structure in the first region and successively arranged in a first direction; and
a second support extending in a second direction intersecting the first direction between the gate structure and the stack in the second region,
wherein at least one of the first supports includes a first protrusion protruding toward the second region, and
wherein the second support includes a second protrusion protruding toward the first region.

2. The semiconductor device of claim 1, wherein at least one of the first supports comprises:
a first body portion extending through the gate structure; and
the first protrusion protruding from the first body portion within the gate structure.

3. The semiconductor device of claim 1, wherein the second support comprises:
a second body portion extending between the gate structure and the stack; and
a second protrusion protruding from the second body portion within the gate structure.

4. The semiconductor device of claim 1, further comprising:
third supports extending through the gate structure in the first region and extending in the first direction; and
fourth supports extending through the gate structure in the second region and successively arranged in the first direction.

5. The semiconductor device of claim 4,
wherein at least one of the third supports includes a third body portion extending through the gate structure and a third protrusion protruding from the third body portion toward the second region within the gate structure, and
wherein at least one of the fourth supports includes a fourth body portion extending through the gate structure and a fourth protrusion protruding from the fourth body portion toward the first region within the gate structure.

6. The semiconductor device of claim 1, wherein the gate structure comprises:
a first portion having a first height; and
a second portion positioned on the first portion and having a second height less than the first height.

7. The semiconductor device of claim 6, further comprising:
channel structures each including a first sub-channel structure extending through the first portion, and a second sub-channel structure extending through the second portion and connected to the first sub-channel structure.

8. The semiconductor device of claim 7, wherein at least one of the first protrusion or the second protrusion is positioned at a level corresponding to the first sub-channel structure.

9. The semiconductor device of claim 1,
wherein the gate structure includes insulating layers and conductive layers alternately stacked, and
wherein the semiconductor device further comprises contact vias extending through the gate structure to be respectively connected to the conductive layers, and each contact via positioned within the first region or the second region.

10. The semiconductor device of claim 1, further comprising:
a peripheral circuit positioned over the substrate; and
a contact plug extending through the stack to be electrically connected to the peripheral circuit, and positioned in the second region.

11. A semiconductor device comprising:
a gate structure including a first portion and a second portion positioned on the first portion;
a stack positioned at a level corresponding to the gate structure;
first supports extending through the gate structure and successively arranged in a first direction; and
a second support extending in a second direction intersecting the first direction between the gate structure and the stack,
wherein at least one of the first supports includes a first protrusion protruding toward the second support, the second support includes a second protrusion protruding toward the first supports, and
wherein at least one of the first protrusion or the second protrusion is positioned at a level corresponding to the first portion.

12. A semiconductor device of claim 11, further comprising:
a substrate including a first region and a second region,
wherein the gate structure is positioned over the substrate and extends from the first region to the second region, and
wherein the stack is positioned over the substrate within the second region.

13. The semiconductor device of claim 12,
wherein the first protrusion protrudes toward the second region, and
wherein the second protrusion protrudes toward the first region.

14. The semiconductor device of claim 12,
wherein the gate structure includes insulating layers and conductive layers alternately stacked, and
wherein the semiconductor device further comprises contact vias extending through the gate structure to be respectively connected to the conductive layers, and each contact via positioned within the first region or the second region.

15. The semiconductor device of claim 12, further comprising:
a peripheral circuit positioned over the substrate; and
a contact plug extending through the stack to be electrically connected to the peripheral circuit, and positioned in the second region.

16. The semiconductor device of claim 11, wherein at least one of the first supports respectively comprises:
a first body portion extending through the gate structure; and
a first protrusion protruding from the first body portion within the gate structure.

17. The semiconductor device of claim 11, wherein the second support comprises:
a second body portion extending between the gate structure and the stack; and
the second protrusion protruding from the second body portion within the first gate structure.

18. The semiconductor device of claim 11, further comprising:
third supports extending through the gate structure in the first region and extending in the first direction; and
fourth supports extending through the gate structure in the second region and successively arranged in the first direction.

19. The semiconductor device of claim 18,
wherein at least one of the third supports includes a third body portion extending through the gate structure and a third protrusion protruding from the third body portion toward the fourth supports within the gate structure, and
wherein at least one of the fourth supports includes a fourth body portion extending through the gate structure and a fourth protrusion protruding from the fourth body portion toward the third supports within the gate structure.

20. The semiconductor device of claim 11,
wherein the first portion has a first height, and
wherein the second portion has a second height less than the first height.

21. The semiconductor device of claim 11, further comprising:
channel structures each including a first sub-channel structure extending through the first portion, and a second sub-channel structure extending through the second portion to be connected to the first sub-channel structure.

22. The semiconductor device of claim 21, wherein at least one of the first protrusion or the second protrusion is positioned at a level corresponding to the first sub-channel structure.
